(19) United States
(12) Patent Application Publication
(10) Pub. No.: US 2022/0244758 A1
(43) Pub. Date: Aug. 4, 2022

(54) FOLDABLE DISPLAY TERMINAL

(71) Applicant: KunShan Go-Visionox Opto-Electronics Co., Ltd., Kunshan (CN)

(72) Inventors: Fu LIAO, Kunshan (CN); Xuebin LI, Kunshan (CN); Desong YAN, Kunshan (CN); Liwei DING, Kunshan (CN); Kanglong SUN, Kunshan (CN); Zhaoji ZHU, Kunshan (CN)

(73) Assignee: KunShan Go-Visionox Opto-Electronics Co., Ltd., Kunshan (CN)

(21) Appl. No.: 17/720,548

(22) Filed: Apr. 14, 2022

Related U.S. Application Data
(63) Continuation of application No. PCT/CN2021/083267, filed on Mar. 26, 2021.

(30) Foreign Application Priority Data
Apr. 27, 2020 (CN) 202010344749.3

(51) Int. Cl. G06F 1/16

(52) U.S. Cl. CPC G06F 1/1616; G06F 1/1681; G06F 1/1624; G06F 1/1652

(57) ABSTRACT

A foldable display terminal, including: a flexible display screen, a rotating assembly, and a first shell and a second shell that are connected by the rotating assembly along a first direction, where each of the first shell and the second shell includes a first surface and a second surface that are oppositely disposed. When the first shell and the second shell are driven by the rotating assembly to rotate until the flexible display screen is in a folded state to dispose the first surface of the first shell face to the first surface of the second shell, at least a partial area of the flexible display screen slides to the second surface of the first shell and/or the second surface of the second shell.

### CROSS-REFERENCE TO RELATED APPLICATIONS

This application is a Continuation Application of PCT application No. PCT/CN2021/083267, filed on Mar. 26, 2021, which claims priority of CN patent application 202010344749.3, filed on Apr. 27, 2020. Both of the aforementioned applications are incorporated herein by reference in their entireties.

### TECHNICAL FIELD

This application relates to the field of display device technologies, and in particular, to a foldable display terminal.

### BACKGROUND

With development of flexible display technologies, foldable display terminals rise to the occasion. When a current foldable display terminal, for example, a foldable mobile phone, is folded, a display screen is covered by a shell. In this case, a secondary screen usually needs to be disposed on the shell for information display and human-computer interactions when the foldable display terminal is in a folded state. Disposing of the secondary screen undoubtedly brings some drawbacks, such as system costs and screen costs are increased, and an overall thickness is affected.

### SUMMARY

In view of this, the embodiments of this application provide a foldable display terminal, to resolve a problem such as costs of a foldable display terminal are increased due to an additionally disposed secondary screen.

This application provides a foldable display terminal, including: a flexible display screen, a rotating assembly; and a first shell and a second shell that are connected by the rotating assembly along a first direction, wherein each of the first shell and the second shell comprises a first surface and a second surface that are oppositely disposed; wherein when the first shell and the second shell are driven by the rotating assembly to rotate until the first surface of the first shell and the first surface of the second shell are coplanar with each other, the flexible display screen is in an unfolded state on a plane where the first surface of the first shell and the first surface of the second shell are located; and when the first shell and the second shell are driven by the rotating assembly to rotate until the flexible display screen is in a folded state to dispose the first surface of the first shell face to the first surface of the second shell, at least a partial area of the flexible display screen slides to the second surface of the first shell and/or the second surface of the second shell.

According to the foldable display terminal provided in the embodiments of this application, when the foldable display terminal is in an unfolded state, an entire display surface of the flexible display screen is exposed outside for display; and when the foldable display terminal is in a folded state, at least a partial area of the flexible display screen is exposed outside for display, that is, the same flexible display screen is used as not only a main screen in the unfolded state, but also a secondary screen in the folded state. In this case, there is no need to additionally dispose a secondary screen, thereby reducing system costs and screen costs and avoiding increasing a thickness of the foldable display terminal.

### BRIEF DESCRIPTION OF DRAWINGS

FIG. 1 is a schematic diagram of a foldable display terminal in an unfolded state according to an embodiment of this application;

FIG. 2 is a schematic diagram of the foldable display terminal shown in FIG. 1 in a folded state; and

FIG. 3 is a partially enlarged view of the foldable display terminal shown in FIG. 1.

### DETAILED DESCRIPTION OF THE EMBODIMENTS

In order to make objectives, technical means and advantages of this application clearer, a further detailed description on this application will be given below in combination with accompanying drawings.

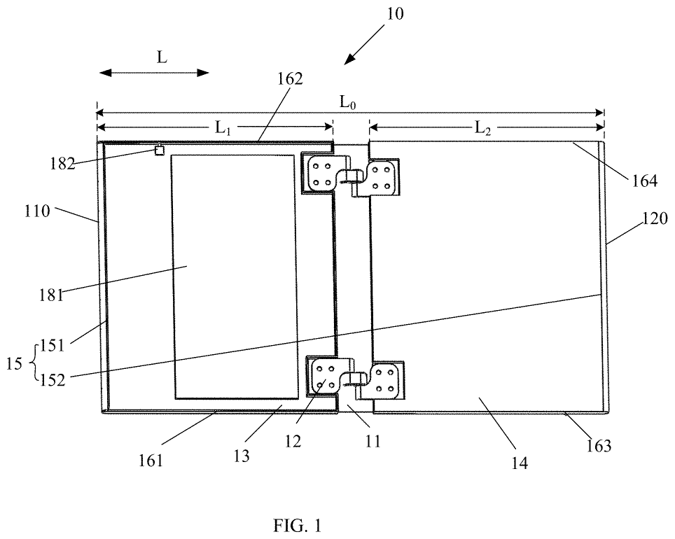

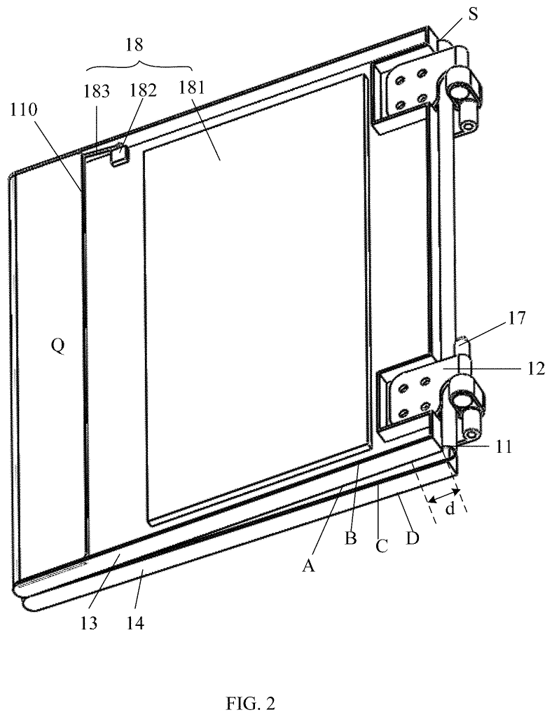

FIG. 1 is a schematic diagram of a foldable display terminal in an unfolded state according to an embodiment of this application. FIG. 2 is a schematic diagram of the foldable display terminal shown in FIG. 1 in a folded state. To show a structure of the foldable display terminal clearly, FIG. 1 shows a rear view of the foldable display terminal in an unfolded state, namely a view of one side of the foldable display terminal where a non-display surface is located. It can be seen in combination with FIG. 1 and FIG. 2 that the foldable display terminal 10 includes: a flexible display screen 11, a rotating assembly 12 along a first direction; and a first shell 13 and a second shell 14 that are connected by the rotating assembly 12. Each of the first shell 13 and the second shell 14 includes a first surface and a second surface that are oppositely disposed. When the first shell 13 and the second shell 14 are driven by the rotating assembly 12 to rotate until the first surface of the first shell 13 and the first surface of the second shell 14 are coplanar with each other, as shown in FIG. 1, the flexible display screen 11 is in an unfolded state on a plane where the first surface of the first shell 13 and the first surface of the second shell 14 are located. When the first shell 13 and the second shell 14 are driven by the rotating assembly 12 to rotate until the flexible display screen 11 is in a folded state to dispose the first surface of the first shell 13 face to the first surface of the second shell 14, as shown in FIG. 2, at least a partial area Q of the flexible display screen 11 slides to the second surface of the first shell 13 and/or the second surface of the second shell 14.

Two working states, namely an unfolded state and a folded state, of the foldable display terminal 10 can be implemented by using the rotating assembly 12 between the first shell 13 and the second shell 14. Specifically, as shown in FIG. 2, the first shell 13 includes a first surface A and a second surface B that are oppositely disposed. The second shell 14 includes a first surface C and a second surface D that are oppositely disposed. When the first shell 13 and the second shell 14 are respectively driven by the rotating assembly 12 to rotate in directions away from each other until the first surface A of the first shell 13 and the first surface C of the second shell 14 are coplanar, the foldable display terminal 10 is in the unfolded state. When the first shell 13 and the second shell 14 are respectively driven by the rotating assembly 12 to rotate in directions close to each other until the first surface A of the first shell 13 face to the first surface C of the second shell 14, the foldable display terminal 10 is in the folded state.

In this embodiment, as shown in FIG. 1 and FIG. 2, in a sliding direction L of the flexible display screen 11, in a case that a length of the rotating assembly 12 is ignored, a length L0 of the flexible display screen 11 is less than or equal to a sum of a length L1 of the first surface A of the first shell 13 and a length L2 of the first surface C of the second shell 14.

The rotating assembly 12 may be, for example, a hinge. A specific implementation of the rotating assembly 12 is not limited in this embodiment. The flexible display screen 11 includes a display panel used for display, and may further include a flexible support member, for example, an ultra-thin steel sheet, located below the display panel and used for providing a support function.

According to the foldable display terminal 10 provided in this embodiment, when the foldable display terminal 10 is in the unfolded state, an entire display surface of the flexible display screen 11 is exposed outside for display; and when the foldable display terminal 10 is in the folded state, the at least a partial area Q of the flexible display screen 11 is exposed outside for display, that is, the same flexible display screen 11 is used as not only a main screen in the unfolded state, but also a secondary screen in the folded state. In this case, there is no need to additionally dispose a secondary screen, thereby reducing system costs and screen costs and avoiding increasing a thickness of the foldable display terminal 10.

A specific structure of the foldable display terminal 10 in different embodiments is described below in detail in combination with FIG. 1 and FIG. 2.

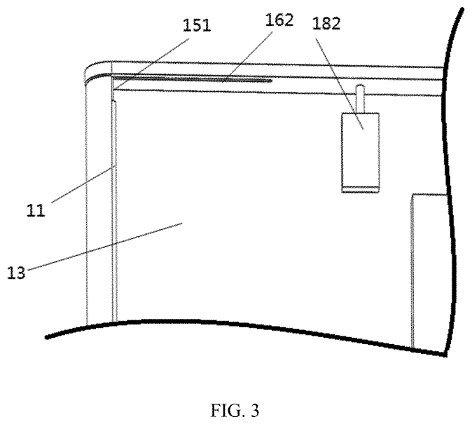

FIG. 3 is a partially enlarged view of the foldable display terminal shown in FIG. 1. In one embodiment, as shown in FIG. 1, FIG. 2, and FIG. 3, the foldable display terminal 10 further includes a plurality of support rods 15 extending along a second direction perpendicular to the first direction and a plurality of rails 16 extending along the first direction. The support rods 15 are connected to the flexible display screen 11. The foldable display terminal 10 further includes the rails 16 disposed in two sides of each of the first shell 13 and the second shell 14 in the second direction; and two ends of each of the support rods 15 are slidably disposed in the corresponding rails.

Specifically, referring to FIG. 1, the foldable display terminal 10 includes two support rods 15, namely a first support rod 151 and a second support rod 152. The first support rod 151 and the second support rod 152 are respectively fixedly connected to two short sides of the flexible display screen 11 along the first direction. Each of two opposite ends of both the first support rod 151 and the second support rod 152 is provided with a sliding block. The rails 16 comprise a first rail 161, a second rail 162, a third rail 163 and a fourth rail 164. The first rail 161 and the second rail 162 are parallel to each other and located in two ends of the first shell 13. The third rail 163 and the fourth rail 164 are parallel to each other and located in two ends of the second shell 14. The first support rod 151 is connected between the first rail 161 and the second rail 162 and two ends of the first support rod 151 are slidable in the first rail 161 and the second rail 162. And the second support rod 152 is connected between the third rail 163 and the fourth rail 164 and two ends of the second support rod 152 are slidable in the third rail 163 and the fourth rail 164. The sliding blocks at both ends of the first support rod 151 can slide along the first rail 161 and the second rail 162 that are on the first shell 13, and the sliding blocks at both ends of the second support rod 152 can slide along the third rail 163 and the fourth rail 164 that are on the second shell 14, thereby implementing sliding of the flexible display screen 11.

In another embodiment, when an area of the flexible display screen 11 that is folded to the second surface D of the second shell 14 is large enough, the first support rod 151 slides onto the third rail 163 and the fourth rail 164, and slides along the third rail 163 and the fourth rail 164. Alternatively, when an area of the flexible display screen 11 that is folded to the second surface B of the first shell 13 is large enough, the second support rod 152 slides onto the first rail 161 and the second rail 162, and slides along the first rail 161 and the second rail 162.

Sliding directions of the first support rod 151 and the second support rod 152 are the same or opposite. When the sliding directions of the first support rod 151 and the second support rod 152 are the same, a secondary screen is formed only on the second surface B of the first shell 13, or the secondary screen is formed only on the second surface D of the second shell 14. When the sliding directions of the first support rod 151 and the second support rod 152 are opposite, a first secondary screen is formed on the second surface B of the first shell 13, and a second secondary screen is formed on the second surface D of the second shell 14.

According to the foldable display terminal 10 provided in this embodiment, the support rods 15 are disposed. In one aspect, the support rods 15 are in sliding fit with the rails, so that sliding of the flexible display screen 11 is implemented, thereby achieving a simple structure and easy implementation; and in another aspect, the support rods provides a support function for the flexible display screen 11 in a sliding process of the flexible display screen 11, which ensures that a surface of the flexible display screen 11 is even.

In one embodiment, the first shell 13 and the second shell 14 comprise a plurality of flanged edges (not shown in the figure) located in the ends and covering an edge of the flexible display screen 11. The flanged edges refer to an area on an edge of a corresponding shell that extends from the first shell 13 or the second shell 14 and is formed after being folded by 180 degrees. In this way, a U-shaped groove is formed at an edge of the shell.

Specifically, the flanged edges comprise a first flanged edge and a second flanged edge disposed in two ends of the first shell and a third flanged edge and a fourth flanged edge disposed in two ends of the second shell. The rails 16 comprise a first rail 161, a second rail 162 parallel to the first rail 161, a third rail 163 and a fourth rail 164 parallel to the third rail 163. The first shell 13 comprises a first U-shaped groove and a second U-shaped groove, the first flanged edge is disposed in the first U-shaped groove, the second flanged edge is disposed in the second U-shaped groove, the first rail 161 is located at a bottom of the first U-shaped groove, and the second rail is located at a bottom of the second U-shaped groove. The second shell 14 comprises a third U-shaped groove and a fourth U-shaped groove, the third flanged edge is disposed in the third U-shaped groove, the fourth flanged edge is disposed in fourth U-shaped groove, the third rail 163 is located at a bottom of the third U-shaped groove, and the fourth rail is located at a bottom of the fourth U-shaped groove.

The flanged edge is equivalent to a pressure plate covering an edge of the flexible display screen 11. When the flexible display screen 11 slides along the rail, the flanged edge can limit the edge of the flexible display screen 11 in a direction perpendicular to the first surface and the second surface, preventing the edge of the flexible display screen 11 from being warped or folded. Therefore, it can be ensured that a display surface presented by the flexible display screen 11 is even.

Further, in one embodiment, on one side close to the rotating assembly 12, there is a predetermined distance d between an end of the flanged edges and an end S of one shell where the flanged edges are located.

Specifically, referring to FIG. 2, the first flanged edge and the second flanged edge are used as an example. The first flanged edge and the second flanged edge are respectively located on two sides of the first shell 13 that respectively correspond to the long sides of the body of the screen, and are suspended on the first surface A. Each of the first flanged edge and the second flanged edge includes an end close to the rotating assembly 12. The first shell 13 includes an end S close to the rotating assembly 12. There is a predetermined distance d between the end of each of the first flanged edge and the second flanged edge and the end of the first shell 13.

Due to the predetermined distance d between the end of the flanged edge and the end S of the shell where the flanged edge is located, in a process when the foldable display terminal 10 is folded and then unfolded or is unfolded and then folded, a yield space is provided for the flexible display screen 11, thereby preventing a position of the flexible display screen 11 from being limited in a direction parallel to the first surface and the second surface. For example, when two opposite ends of the flexible display screen 11 respectively slide in opposite directions to form two secondary screens, an area, corresponding to the rotating assembly 12, of the flexible display screen 11 in the unfolded state may move in a direction away from the rotating assembly 12 without being limited by the flanged edge.

In one embodiment, as shown in FIG. 2, the foldable display terminal 10 further includes an angle sensor 17 and a driving assembly 18. The angle sensor 17 is fixedly connected to the rotating assembly 12 and configured to detect rotation angles and directions of the rotating assembly 12. The driving assembly 18 is fixed on the first shell 13 and/or the second shell 14 and configured to drive the flexible display screen 11 to slide synchronously based on the rotation angles and the directions of the rotating assembly 12. In this way, the rotation and the sliding are controlled to be synchronous, so that the flexible display screen 11 can be prevented from being dragged or extruded in a process when the first shell 13 and the second shell 14 are respectively driven by the rotating assembly 12 to rotate, thereby improving reliability of the foldable display terminal 10.

In this embodiment, as shown in FIG. 1 and FIG. 2, the foldable display terminal 10 further includes a transmission component 183. The driving assembly 18 includes a central control circuit board 181 fixed on the first shell 13 and/or the second shell 14 and at least one motor. The central control circuit board 181 is configured to control rotational speeds and directions of the at least one motor 182 based on the rotation angles and the directions of the rotating assembly 12 and the flexible display screen 11 is driven by the at least one motor 182 to slide synchronously via the transmission component 183. The central control circuit board 181 is used to control the flexible display screen 11 to slide synchronously, thereby implementing a simple structure and high control precision.

In one embodiment, the transmission component 183 includes a pulley and a synchronous belt. The pulley is coaxially fixed to the at least one motor 182. The synchronous belt includes a first end and a second end that are oppositely disposed. The first end of the synchronous belt is fixed to the pulley. The second end of the synchronous belt is fixed to the flexible display screen 11. For example, the second end of the synchronous belt is fixed on the support rod 15, thereby implementing fixation to the flexible display screen 11. In this case, the synchronous belt is contracted in a curled manner or elongated in an expanded manner under rotation of the at least one motor 182, so as to implement effects that the flexible display screen 11 slides in two opposite directions, thereby ensuring that when the foldable display terminal 10 is in the unfolded state, the flexible display screen 11 slides to the first surfaces of the first shell 13 and the second shell 14, to form a main screen; and that when the foldable display terminal 10 is in the folded state, the at least a partial area Q of the flexible display screen 11 slides to the second surface B of the first shell 13 and/or the second surface D of the second shell 14, to form a secondary screen.

In one embodiment, as shown in FIG. 1 and FIG. 2, the flexible display screen 11 includes a first end 110 and a second end 120 that are oppositely disposed. The at least one motor 182 is fixed on the second surface B of the first shell 13. The at least one motor 182 is fixedly connected to the first end 110 of the flexible display screen 11 by using the transmission component 183. The second end 120 of the flexible display screen 11 is fixedly connected to the second shell 14.

According to the foldable display terminal 10 provided in this embodiment, in a process when the first shell 13 and the second shell 14 are respectively driven by the rotating assembly 12 to rotate in directions close to each other, the at least one motor 182 rotates to drive the synchronous belt to be contracted in a curled manner, so as to further drive the first end 110 of the flexible display screen 11 to slide towards the second surface B of the first shell 13, to form a secondary screen. In a process when the first shell 13 and the second shell 14 are respectively driven by the rotating assembly 12 to rotate in directions away from each other, the at least one motor 182 rotates to drive the synchronous belt to be elongated in an expanded manner, so as to further drive the first end 110 of the flexible display screen 11 to slide towards the first surface A of the first shell 13, to form a main screen.

In one embodiment, the at least one motor 182 includes two motors, the two motors are respectively fixed on the second surfaces of the first shell 13 and the second shell 14. The two motors have the same rotational speed and direction, or the two motors have the same rotational speed and opposite directions.

For example, the at least one motor 182 includes a first motor and a second motor, the first motor is fixed on the second surface B of the first shell 13, and the second motor is fixed on the second surface D of the second shell 14. When the two motors have the same rotational speed and direction, the first end 110 and the second end 120 of the flexible display screen 11 slide in a same direction, so as to form a secondary screen on the second surface B of the first shell 13 or the second surface D of the second shell 14. When the two motors have the same rotational speed and opposite directions, the first end 110 and the second end 120 of the flexible display screen 11 slide in opposite directions, so as to form a secondary screen on the second surface B of the first shell 13 and the second surface D of the second shell 14, respectively.

In one embodiment, the driving assembly 18 further includes a central control circuit board 181 fixed on the first shell and/or the second shell and configured to: when the flexible display screen is in the unfolded state, control an entire display surface of the flexible display screen to display; and when the flexible display screen is in the folded state, control at least a partial area of the flexible display screen to display.

In this embodiment, the rotation angles detected by the angle sensor are used as a switch instruction of a control method of the central control circuit board 181. For example, when a rotation angle detected by the angle sensor 17 is greater than a first angle threshold (for example, 85 degrees), the central control circuit board 181 controls an entire display surface of the flexible display screen 11 to display; when a rotation angle detected by the angle sensor 17 is smaller than a second angle threshold (for example, 5 degrees), the central control circuit board 181 controls at least a partial area of the flexible display screen 11 to display, and the at least a partial area is an area folded to the second surface B of the first shell 13 and/or the second surface D of the second shell 14.

In one embodiment, an end, away from the rotating assembly 12, of each of the first shell 13 and the second shell 14, includes a lower support plate and an upper cover plate, and the flexible display screen 11 is located between the lower support plate and the upper cover plate. In other words, the end of each of the first shell 13 and second shell 14 is implemented as a tunnel structure, and the flexible display screen 11 passes through the tunnel. In this way, the lower support plate is used to support the flexible display screen 11, and the upper cover plate is used to manually open or fold the foldable display terminal 10 when being touched by a user. Further, each of the lower support plate and the upper cover plate includes an arc-shaped surface, to prevent the flexible display screen from being damaged.

The foregoing descriptions are merely preferable embodiments of this application, but are not intended to limit this application. Any modification, equivalent replacement, or improvement made without departing from the spirit and principle of this application shall fall the protection scope of this application.

What is claimed is:

1. A foldable display terminal, comprising:
a flexible display screen,
a rotating assembly; and
a first shell and a second shell that are connected by the rotating assembly along a first direction, wherein each of the first shell and the second shell comprises a first surface and a second surface that are oppositely disposed;
wherein when the first shell and the second shell are driven by the rotating assembly to rotate until the first surface of the first shell and the first surface of the second shell are coplanar with each other, the flexible display screen is in an unfolded state on a plane where the first surface of the first shell and the first surface of the second shell are located; and when the first shell and the second shell are driven by the rotating assembly to rotate until the flexible display screen is in a folded state to dispose the first surface of the first shell face to the first surface of the second shell, at least a partial area of the flexible display screen slides to the second surface of the first shell and/or the second surface of the second shell.

2. The foldable display terminal according to claim 1, further comprising a plurality of support rods extending along a second direction perpendicular to the first direction and a plurality of rails extending along the first direction, wherein the support rods are connected to the flexible display screen;
the rails disposed in two sides of each of the first shell and the second shell in the second direction; and two ends of each of the support rods are slidably disposed in the corresponding rails.

3. The foldable display terminal according to claim 2, wherein the support rods comprise a first support rod and a second support rod, and the first support rod and the second support rod are respectively fixed at two ends of the flexible display screen along the first direction.

4. The foldable display terminal according to claim 3, wherein the rails comprise a first rail, a second rail, a third rail and a fourth rail, the first rail and the second rail are parallel to each other and located in two ends of the first shell, the third rail and the fourth rail are parallel to each other and located in two ends of the second shell, the first support rod is connected between the first rail and the second rail and two ends of the first support rod are slidable in the first rail and the second rail, and the second support rod is connected between the third rail and the fourth rail and two ends of the second support rod are slidable in the third rail and the fourth rail.

5. The foldable display terminal according to claim 2, wherein the first shell and the second shell comprise a plurality of flanged edges located in the ends and covering an edge of the flexible display screen.

6. The foldable display terminal according to claim 5, wherein on one side close to the rotating assembly, there is a predetermined distance between an end of the flanged edges and an end of one shell where the flanged edges are located.

7. The foldable display terminal according to claim 5, wherein the flanged edges comprise a first flanged edge and a second flanged edge disposed in two ends of the first shell and a third flanged edge and a fourth flanged edge disposed in two ends of the second shell, and the rails comprise a first rail, a second rail parallel to the first rail, a third rail and a fourth rail parallel to the third rail; and
the first shell comprises a first U-shaped groove and a second U-shaped groove, the first flanged edge is disposed in the first U-shaped groove, the second flanged edge is disposed in the second U-shaped groove, the first rail is located at a bottom of the first U-shaped groove, and the second rail is located at a bottom of the second U-shaped groove; and
the second shell comprises a third U-shaped groove and a fourth U-shaped groove, the third flanged edge is disposed in the third U-shaped groove, the fourth flanged edge is disposed in fourth U-shaped groove, the third rail is located at a bottom of the third U-shaped groove, and the fourth rail is located at a bottom of the fourth U-shaped groove.

8. The foldable display terminal according to claim 1, further comprising:
an angle sensor, fixed to the rotating assembly and configured to detect rotation angles and directions of the rotating assembly; and
a driving assembly, fixed on the first shell and/or the second shell and configured to drive the flexible display screen to slide synchronously based on the rotation angles and the directions.

9. The foldable display terminal according to claim 8, further comprising a transmission component, wherein the driving assembly comprises a central control circuit board fixed on the first shell and/or the second shell and at least one motor, and the central control circuit board is configured to control rotational speeds and directions of the at least one motor based on the rotation angles and the directions of the rotating assembly and the flexible display screen is driven by the at least one motor to slide synchronously via the transmission component.

10. The foldable display terminal according to claim 9, wherein the transmission component comprises a pulley and a synchronous belt, the pulley is coaxially fixed to the at least one motor, the synchronous belt comprises a first end and a second end that are oppositely disposed, the first end of the synchronous belt is fixed to the pulley, and the second end of the synchronous belt is fixed to the flexible display screen.

11. The foldable display terminal according to claim 9, wherein the flexible display screen comprises a first end and a second end that are oppositely disposed, the at least one motor is fixed on the second surface of the first shell and fixed to the first end of the flexible display screen by the transmission component, and the second end of the flexible display screen is fixed to the second shell.

12. The foldable display terminal according to claim 9, wherein the at least one motor comprises two motors, the two motors are respectively fixed on the second surface of the first shell and the second surface of the second shell, and the two motors have the same rotational speed and direction.

13. The foldable display terminal according to claim 9, wherein the at least one motor comprises two motors, the two motors are respectively fixed on the second surface of the first shell and the second surface of the second shell, and the two motors have the same rotational speed and opposite directions.

14. The foldable display terminal according to claim 1, further comprising a central control circuit board fixed on the first shell and/or the second shell and configured to: when the flexible display screen is in an unfolded state, control an entire display surface of the flexible display screen to display; and when the flexible display screen is in a folded state, control the at least a partial area of the flexible display screen to display.
